(19) United States
(12) Patent Application Publication
(10) Pub. No.: US 2013/0029267 A1
(43) Pub. Date: Jan. 31, 2013

(54) FLEXOGRAPHIC PRINTING PLATE PRECURSOR FOR THERMAL DEVELOPMENT, AND PROCESS FOR MAKING A FLEXOGRAPHIC PRINTING PLATE

(71) Applicant: Atsushi SUGASAKI, Haibara-gun (JP)

(72) Inventor: Atsushi SUGASAKI, Haibara-gun (JP)

(73) Assignee: FUJIFILM CORPORATION, Tokyo (JP)

(21) Appl. No.: 13/560,350

(22) Filed: Jul. 27, 2012

(30) Foreign Application Priority Data
Jul. 29, 2011 (JP) 2011-166854

(51) Int. Cl. G03F 7/028; G03F 7/20

(52) U.S. Cl. 430/281.1; 430/306

(57) ABSTRACT

A flexographic printing plate precursor for thermal development is provided that comprises a relief-forming layer on/above a support; the relief-forming layer comprising (Component A) a polymer having a glass transition temperature (Tg) of at least 25° C., (Component B) a photopolymerization initiator, and (Component C) an ethylenically unsaturated compound having a molecular weight of no greater than 3,000.

### TECHNICAL FIELD

The present invention relates to a flexographic printing plate precursor for thermal development, and a process for making a flexographic printing plate.

### BACKGROUND ART

As a process for forming a printing plate by forming asperities in a photosensitive resin layer layered on a support surface area, a method in which a relief-forming layer formed using a photosensitive composition is exposed to UV light through an original image film to thus selectively cure an image area, and an uncured area is removed using a developer, the so-called ‘analogue plate making’, is well known.

A relief printing plate is a letterpress printing plate having a relief layer with asperities, and such a relief layer with asperities is obtained by patterning a relief-forming layer comprising a photosensitive composition containing as a main component, for example, an elastomeric polymer such as a synthetic rubber, a resin such as a thermoplastic resin, or a mixture of a resin and a plasticizer, thus forming asperities. Among such relief printing plates, one having a soft relief layer is sometimes called a flexographic plate.

JP-A-5-19469 (JP-A denotes a Japanese unexamined patent application publication), JP-A-7-234502, JP-A-2003-131376, and JP-A-2007-511791 disclose a process for producing a flexographic printing plate by a thermal development process.

### SUMMARY OF INVENTION

It is an object of the present invention to provide a flexographic printing plate precursor for thermal development that has excellent thermal developability and gives a flexographic printing plate having excellent printing durability. Furthermore, it is to provide a process for making a flexographic printing plate employing the flexographic printing plate precursor for thermal development, and a flexographic printing plate obtained thereby.

The object of the present invention has been attained by means described in <1> and <12>. They are described below together with <2> to <11> and <13> to <16>, which are preferred embodiments.

<1> A flexographic printing plate precursor for thermal development, comprising a relief-forming layer on/above a support, the relief-forming layer comprising (Component A) a polymer having a glass transition temperature (Tg) of at least 25° C., (Component B) a photopolymerization initiator, and (Component C) an ethylenically unsaturated compound having a molecular weight of no greater than 3,000,
<2> the flexographic printing plate precursor for thermal development according to <1>, wherein the relief-forming layer further comprises (Component D) a plasticizer,
<3> the flexographic printing plate precursor for thermal development according to <1> or <2>, wherein Component A has a polar group,
<4> the flexographic printing plate precursor for thermal development according to <3>, wherein the polar group of Component A is selected from the group consisting of an ester bond, an ether bond, and a hydroxy group,
<5> the flexographic printing plate precursor for thermal development according to any one of <1> to <4>, wherein Component A is selected from the group consisting of polyvinyl alcohol and a derivative thereof, polyvinyl acetal and a derivative thereof, polyester, polyester polyurethane, polylactic acid, a (meth)acrylic resin, a polycarbonate resin, and a polysaccharide,
<6> the flexographic printing plate precursor for thermal development according to any one of <1> to <5>, wherein Component A is polyvinyl acetal and/or a derivative thereof,
<7> the flexographic printing plate precursor for thermal development according to any one of <1> to <6>, wherein the relief-forming layer comprises Component A at 30 to 90 wt %,
<8> the flexographic printing plate precursor for thermal development according to <2>, wherein the relief-forming layer comprises Component D at 1 to 30 wt %,
<9> the flexographic printing plate precursor for thermal development according to <2> or <8>, wherein Component D is selected from the group consisting of a citric acid derivative, a polyethylene glycol, and a polypropylene glycol,
<10> the flexographic printing plate precursor according to any one of <1> to <9>, wherein Component C is a 2- to 6-functional (meth)acrylate,
<11> the flexographic printing plate precursor according to any one of <1> to <10>, wherein the flexographic printing plate precursor further comprises an adhesive layer between the relief-forming layer and the support,
<12> a process for making a flexographic printing plate, comprising (Step a) an exposure step of imagewise exposing a relief-forming layer of a flexographic printing plate precursor, (Step b) a heating step of heating the exposed flexographic printing plate precursor at a temperature of 40° C. to 270° C., and (Step c) a development step of removing an unexposed portion that has become softened by heating, the flexographic printing plate precursor comprising the flexographic printing plate precursor for thermal development according to any one of <1> to <11>,
<13> the process for making a flexographic printing plate according to <12>, wherein the exposure step is a step of imagewise irradiating the relief-forming layer with UV,
<14> the process for making a flexographic printing plate according to <12> or <13>, wherein the exposure step is a step of curing an exposed portion by crosslinking and/or polymerization,
<15> the process for making a flexographic printing plate according to any one of <12> to <14>, wherein the development step comprises a step of removing the unexposed portion of the relief-forming layer that has become softened by heating by contacting with an absorbent member, and
<16> the process for making a flexographic printing plate according to any one of <12> to <15>, wherein it further comprises a backside irradiation step of irradiating the relief-forming layer by applying actinic radiation toward the support and making it pass through the support.

### DESCRIPTION OF EMBODIMENTS

The present invention is explained in detail below.

### (Flexographic Printing Plate Precursor for Thermal Development)

The flexographic printing plate precursor for thermal development (hereinafter, also simply called a flexographic printing plate precursor) of the present invention comprises a relief-forming layer on/above a support, this relief-forming layer comprising (Component A) a polymer having a glass transition temperature (Tg) of at least 25° C., (Component B) a photopolymerization initiator, and (Component C) an ethylenically unsaturated compound having a molecular weight of no greater than 3,000.

In the present invention, the relief-forming layer of the flexographic printing plate precursor is a layer formed from a resin composition for a relief-forming layer (hereinafter, also simply called a ‘resin composition’) comprising at least Component A, Component B, and Component C, and if necessary it may be subjected to drying.

In the present invention, the notation ‘lower limit to upper limit’, which expresses a numerical range, has the same meaning as ‘at least the lower limit but no greater than the upper limit’, and the notation ‘upper limit to lower limit’ has the same meaning as ‘no greater than the upper limit but at least the lower limit’. That is, they express numerical ranges that include the upper limit and the lower limit.

Furthermore, ‘(Component A) a polymer having a glass transition temperature (Tg) of at least 25° C.’, etc. may also be called simply ‘Component A’, etc., ‘(Step a) an exposure step of imagewise exposing a relief-forming layer of a flexographic printing plate precursor’, etc. may also be called simply ‘Step a’, etc.

As a result of an intensive investigation, the present inventor has found that the use of a polymer having a glass transition temperature (Tg) of at least 25° C. as Component A enables a flexographic printing plate precursor having excellent thermal developability to be obtained.

Although the reason is not clear, it is surmised that when a polymer having a Tg of less than 25° C. such as a conventionally used thermoplastic elastomer is used, an exposed portion (cured portion) undergoes thermal melting by heating during thermal development, but in the present invention it is difficult for such thermal melting to occur, and a sharp relief shape can be maintained.

Furthermore, when Component A has a polar group such as an ester bond, an ether bond, or a hydroxy group, due to interaction between the polar groups of Component A, the strength of a relief layer obtained further improves, and a flexographic printing plate having better printing durability is obtained.

Moreover, it has been found that due to the use of Component A, a flexographic printing plate that is obtained exhibits high laydown for both an aqueous ink and a solvent ink (oil-based ink and UV ink). Although the detailed mechanism is unclear, it is surmised that laydown depends on (I) ease of loading of an ink on a printing plate and (II) ease of transfer of an ink on a printing plate onto a printing medium (paper, etc.).

A synthetic rubber, which has been used conventionally as a relief layer of a flexographic printing plate, has high hydrophobicity, is good for a solvent ink in terms of (I) and (II), and exhibits high laydown. On the other hand, due to high hydrophobicity a synthetic rubber has poor ink loading for an aqueous ink, that is, it has poor laydown due to it being poor in terms of (I) above.

Furthermore, since a polyurethane elastomer, which is used in for example Patent Document 1, etc., has a urethane bond, which is a polar group, laydown of an aqueous ink is good. On the other hand, when a solvent ink is used, the solvent ink penetrates into a soft segment of the polyurethane elastomer, and (II) above is poor.

In contrast thereto, as a result of use of the flexographic printing plate precursor of the present invention comprising Component A, it has an appropriate balance between hydrophilicity and hydrophobicity, penetration of various types of inks is suppressed, and high laydown is exhibited for both an aqueous ink and a solvent ink. In particular, when Component A has a polar group such as an ester bond, an ether bond, or a hydroxy group, the balance between hydrophilicity and hydrophobicity is good.

In the present specification, with respect to explanation of the flexographic printing plate precursor, a layer comprising Component A to Component C and having a flat surface as an image formation layer that is subjected to an exposure step is called a relief-forming layer, and a layer that is formed by subjecting the relief-forming layer to exposure and development to form asperities on the surface is called a relief layer.

Components forming the relief-forming layer are explained below.

### (Component A) Polymer Having Glass Transition Temperature (Tg) of at Least 25° C.

In the present invention, the relief-forming layer comprises (Component A) a polymer having a glass transition temperature (Tg) of at least 25° C. When Component A has a plurality of Tgs, for example, when it is a block copolymer, all of the Tgs of Component A are at least 25° C.

The upper limit for the glass transition temperature of Component A is not particularly limited, but it is preferably no greater than 200° C. That is, the glass transition temperature of Component A is preferably 25° C. to 200° C., more preferably 30° C. to 150° C., and yet more preferably 40° C. to 120° C.

When a polymer having a glass transition temperature of 25° C. or greater is used, this polymer is in a glass state at normal temperature. Compared with the case of one that is in a rubber state, thermal molecular motion is considerably suppressed.

Component A may comprise a polymer having a plurality of glass transition temperatures, and preferably has 1 to 3 glass transition temperatures, more preferably 1 or 2 glass transition temperatures, and yet more preferably one glass transition temperature.

Component A is a non-elastomer. An elastomer is academically defined as a polymer generally having a glass transition temperature of no greater than normal temperature (ref. p. 154 of Kagaku Daijiten (Science Dictionary) 2^{nd} Edition, Ed. Foundation for Advancement of International Science, Maruzen Co., Ltd.). An elastomer means a polymer that exhibits rubber elasticity at room temperature, stretches by preferably at least twice when pulled at room temperature, and instantly returns to substantially its original shape when an external force is removed.

In the present invention, Component A is a non-elastomer, has a glass transition temperature that is at least room temperature (25° C.), and does not exhibit rubber elasticity at room temperature.

Component A preferably has a weight-average molecular weight (polystyrene basis measured by GPC) of 5,000 to 500,000, more preferably 10,000 to 400,000, and yet more preferably 15,000 to 300,000.

When the weight-average molecular weight of Component A is at least 5,000, it has excellent shape retention as a polymer on its own, and when it is no greater than 500,000, it has excellent solubility in a solvent and is suitable for preparing a resin composition for the relief-forming layer.

As Component A a normal polymer is appropriately selected, and one type thereof may be used or two or more types thereof may be used in combination. It is necessary to carry out selection while taking into consideration various aspects of performance such as ink transfer properties and thermal developability in particular.

As Component A, one may be selected from a polystyrene resin, a polyester resin, a polyamide resin, a polyurea resin, a polyamideimide resin, a polyurethane resin, a polysulfone resin, a polyether sulfone resin, a polyimide resin, a polycarbonate resin, a hydroxyethylene unit-containing hydrophilic polymer, a (meth)acrylic resin, an acetal resin, an epoxy resin, a polycarbonate resin, a polysaccharide, etc.

In the present invention, polyvinyl acetal and a derivative thereof, a polyester resin, a polyester urethane resin, polylactic acid, a (meth)acrylic resin, a polycarbonate resin, and a polysaccharide are preferable as Component A.

From the viewpoint of storage stability in an uncured state, Component A preferably does not have an ethylenically unsaturated group (ethylenically unsaturated bond).

Component A preferably has a polar group. As described above, when Component A has a polar group, as a result of curing by polymerization of Component C and interaction between the polar groups of Component A, printing durability improves.

Furthermore, an appropriate balance between hydrophilicity and hydrophobicity is obtained, and good laydown is obtained for both an aqueous ink and a solvent ink.

The polar group of Component A is not particularly limited, and a hydroxy group (—OH), a cyano group (—CN), a carboxy group (—C(O)OH), an ester bond (—(CO)O—), an ether bond (—O—), a carbonyl group (—C(O)—), an amino group (—NH₂), an amide bond (—NHC(O)—), an isocyanato group (—NCO), etc. can be cited. Among them, an oxygen-containing polar group is preferable, an ester bond, an ether bond, and a hydroxy group are more preferable, and a hydroxy group is yet more preferable.

The above-mentioned polar groups are preferable since printing durability in particular improves as a result of interaction between the polar groups.

Component A is not particularly limited, but is particularly preferably a polymer having a hydroxy group (—OH) (hereinafter, also called a ‘specific polymer’). The skeleton of the specific polymer is not particularly limited, but is preferably a (meth)acrylic resin, an epoxy resin, a hydroxyethylene unit-containing hydrophilic polymer, a polyvinyl acetal resin, a polyester resin, or a polyurethane resin.

As a (meth)acrylic monomer used for synthesizing the hydroxy group-containing (meth)acrylic resin, for example, a (meth)acrylic acid ester, crotonic acid ester, or (meth)acrylamide having a hydroxy group in the molecule is preferable. Specific examples of these monomers include 2-hydroxyethyl (meth)acrylate, 2-hydroxypropyl (meth)acrylate, and 4-hydroxybutyl (meth)acrylate. A copolymer formed by polymerizing the above with a known (meth)acrylic monomer or vinyl monomer is preferably used.

It is also possible to use an epoxy resin having a hydroxy group in a side chain as the specific polymer. Preferred specific examples include an epoxy resin obtained by polymerizing an adduct of bisphenol A and epichlorohydrin as a starting material monomer.

As the polyester resin, a polyester resin formed from a hydroxycarboxylic acid unit such as polylactic acid can preferably be used. Preferred specific examples of such a polyester resin include those selected from the group consisting of a polyhydroxyalkanoate (PHA), a lactic acid-based polymer, polyglycolic acid (PGA), polycaprolactone (PCL), poly(butylenesuccinic acid), and a derivative or mixture thereof.

It is also preferable to use a polysaccharide as the specific polymer; the polysaccharide is preferably cellulose or a cellulose derivative, and a cellulose derivative can more preferably be used.

Although it is very difficult to dissolve normal cellulose in water, an alcohol, etc., modifying residual OH of a glucopyranose unit with a specific functional group enables water or solvent solubility to be controlled, and a cellulose derivative that is insoluble in water but is made soluble in an alcohol having 1 to 4 carbons in the above way is suitable as Component A in the present invention.

Examples of the cellulose derivative include an alkylcellulose such as ethylcellulose or methylcellulose, hydroxyethylene cellulose, hydroxypropylene cellulose, and cellulose acetate butyrate. Specific examples thereof include the Metolose series manufactured by Shin-Etsu Chemical Co., Ltd. The contents of this series are those formed by replacing some of the hydrogen atoms of hydroxy groups of cellulose with a methyl group (—CH₃), a hydroxypropyl group (—CH₂CHOHCH₃), or a hydroxyethyl group (—CH₂CH₂OH).

Among them, an alkylcellulose is preferable, and ethylcellulose and/or methylcellulose are more preferable.

From the viewpoint of a balance between aqueous ink suitability and solvent ink suitability and also good printing durability, preferred examples of the specific polymer in the present invention include polyvinyl butyral (PVB), an acrylic resin having a hydroxy group in the side chain, and an epoxy resin having a hydroxy group in the side chain.

Specific examples of Component A preferably used in the present invention are cited below.

### (1) Polyvinyl Acetal and its Derivative

Polyvinyl acetal is a compound obtained by converting polyvinyl alcohol (obtained by saponifying polyvinyl acetate) into a cyclic acetal. The polyvinyl acetal derivative is a derivative obtained by modifying the polyvinyl acetal or adding another copolymer constituent.

The acetal content in the polyvinyl acetal derivative (mole % of vinyl alcohol units converted into acetal relative to the total number of moles of vinyl acetate monomer starting material as 100 mole %) is preferably 30 to 90 mole %, more preferably 50 to 85 mole %, and particularly preferably 55 to 78 mole %.

The vinyl alcohol unit in the polyvinyl acetal is preferably 10 to 70 mole % relative to the total number of moles of the vinyl acetate monomer starting material, more preferably 15 to 50 mole %, and particularly preferably 22 to 45 mole %.

Furthermore, the polyvinyl acetal may have a vinyl acetate unit as another component, and the content thereof is preferably 0.01 to 20 mole %, and more preferably 0.1 to 10 mole %. The polyvinyl acetal derivative may further have another copolymerized constitutional unit.

Examples of the polyvinyl acetal include polyvinyl butyral, polyvinyl propylal, polyvinyl ethylal, and polyvinyl methylal. Among them, polyvinyl butyral derivative (PVB) is a derivative that is particularly preferably used.

Polyvinyl butyral is conventionally obtained by converting polyvinyl alcohol into polyvinyl bytyral. Polyvinyl butyral derivatives may be also used.

Examples of the polyvinyl butyral derivatives include an acid-modified PVB in which at least some of the hydroxy groups of the hydroxyethylene units are modified with an acid group such as a carboxy group, a modified PVB in which some of the hydroxy groups are modified with a (meth)acryloyl group, a modified PVB in which at least some of the hydroxy groups are modified with an amino group, a modified PVB in which at least some of the hydroxy groups have introduced thereinto ethylene glycol, propylene glycol, or a multimer thereof.

From the viewpoint of a balance being achieved between engraving sensitivity and film formation properties, the weight-average molecular weight of the polyvinyl acetal is preferably 5,000 to 800,000, more preferably 8,000 to 500,000 and, from the viewpoint of improvement of rinsing properties for engraving residue, particularly preferably 50,000 to 300,000.

Hereinafter, polyvinyl butyral (PVB) and derivatives thereof are cited for explanation as particularly preferable examples of polyvinyl acetal, but are not limited to these.

Polyvinyl butyral has a structure as shown below, and is constituted while including these structural units.

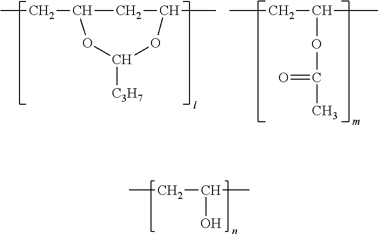

In the above formula, l, m, and n denote the content (mole %) in polyvinyl butyral of the respective repeating units and the relationship l+m+n=100 is satisfied. The butyral content in the polyvinyl butyral and the derivative thereof (value of l in the formula above) is preferably 30 to 90 mole %, more preferably 40 to 85 mole %, and particularly preferably 45 to 78 mole %.

From the viewpoint of a balance being achieved between printing durability and laydown, the weight-average molecular weight of the polyvinyl butyral and the derivative thereof is preferably 5,000 to 800,000, more preferably 8,000 to 500,000.

The PVB derivative is also available as a commercial product, and preferred examples thereof include, from the viewpoint of alcohol dissolving capability (particularly, ethanol), “S-REC B” series and “S-REC K (KS)” series manufactured by SEKISUI CHEMICAL CO., LTD. and “DENKA BUTYRAL” manufactured by DENKI KAGAKU KOGYO KABUSHIKI KAISHA. From the viewpoint of alcohol dissolving capability (particularly, ethanol), “S-REC B” series manufactured by SEKISUI CHEMICAL CO., LTD. and “DENKA BUTYRAL” manufactured by DENKI KAGAKU KOGYO KABUSHIKI KAISHA are more preferable. Among these, particularly preferable commercial products are shown below along with the values l, m, and n in the above formula and the molar weight. Examples of “S-REC B” series manufactured by SEKISUI CHEMICAL CO., LTD. include “BL-1” (l=61, m=3, n=36, weight-average molecular weight: 19,000), “BL-1H” (l=67, m=3, n=30, weight-average molecular weight: 20,000), “BL-2” (l=61, m=3, n=36, weight-average molecular weight: about 27,000), “BL-5” (l=75, m=4, n=21, weight-average molecular weight: 32,000), “BL-S” (l=74, m=4, n=22, weight-average molecular weight: 23,000), “BM-S” (l=73, m=5, n=22, weight-average molecular weight: 53,000), and “BH-S” (l=73, m=5, n=22, weight-average molecular weight: 66,000), and examples of “DENKA BUTYRAL” series manufactured by DENKI KAGAKU KOGYO include “#3000-1” (l=71, m=1, n=28, weight-average molecular weight: 74,000), “#3000-2” (l=71, m=1, n=28, weight-average molecular weight: 90,000), “#3000-4” (l=71, m=1, n=28, weight-average molecular weight: 117,000), “#4000-2” (l=71, m=1, n=28, weight-average molecular weight: 152,000), “#6000-C” (l=64, m=1, n=35, weight-average molecular weight: 308,000), “#6000-EP” (l=56, m=15, n=29, weight-average molecular weight: 381,000), “#6000-CS” (l=74, m=1, n=25, weight-average molecular weight: 322,000), and “#6000-AS” (l=73, m=1, n=26, weight-average molecular weight: 242,000), and examples of “MOWITAL” series manufactured by KURARAY CO., LTD. include “B16H” (m=1 to 4, n=18 to 21), “B20H” (m=1 to 4, n=18 to 21), “B30T” (m=1 to 4, n=24 to 27), “B30H” (m=1 to 4, n=18 to 21), “B30HH” (m=1 to 4, n=11 to 14), “B45M” (m=1 to 4, n=21 to 24), “B45H” (m=1 to 4, n=18 to 21), “B60T” (m=1 to 4, n=24 to 27), “B60H” (m=1 to 4, n=18 to 21), “B60HH” (m=1 to 4, n=12 to 16), and “B75H” (m=1 to 4, n=18 to 21), respectively.

When the relief-forming layer is formed using the PVB derivative as a specific polymer, a method of casting and drying a solution in which a solvent is dissolved is preferable from the viewpoint of smoothness of the film surface.

### (2) A (Meth)Acrylic Resin

As (meth)acrylic resin for use as specific polymer of the present invention, a (meth)acrylic resin may be used which can be obtainable from known (meth)acrylic monomers, and has a hydroxyl group in the molecule.

Preferable examples of the (meth)acrylic monomer having a hydroxy group which can be used in the synthesis of the (meth)acrylic resin having a hydroxy group are as described above.

In the present invention ‘(meth)acryl’ means ‘acryl’ and/or ‘methacryl’ and ‘(meth)acrylate’ means ‘acrylate’ and/or ‘methacrylate.’

As (meth)acrylic resin, the (meth)acrylic monomer other than that having a hydroxy group may comprises as a co-monomer. Examples thereof such an (meth)acrylic monomer include, methyl (meth)acrylate, ethyl (meth)acrylate, n-propyl (meth)acrylate, isopropyl (meth)acrylate, n-butyl (meth)acrylate, isobutyl (meth)acrylate, tert-butyl (meth)acrylate, n-hexyl (meth)acrylate, 2-ethylhexyl (meth)acrylate, lauryl (meth)acrylate, acetoxyethyl (meth)acrylate, phenyl (meth)acrylate, 2-methoxyethyl (meth)acrylate, 2-ethoxyethyl (meth)acrylate, 2-(2-methoxyethoxy)ethyl (meth)acrylate, cyclohexyl (meth)acrylate, t-butyl cyclohexyl (meth)acrylate, benzyl (meth)acrylate, diethylene glycol monomethyl ether (meth)acrylate, diethylene glycol monoethyl ether (meth)acrylate, diethylene glycol monophenyl ether (meth)acrylate, triethylene glycol monomethyl ether (meth)acrylate, triethylene glycol monoethyl ether (meth)acrylate, dipropylene glycol monomethyl ether (meth)acrylate, polyethylene glycol monomethyl ether (meth)acrylate, polypropylene glycol monomethyl ether (meth)acrylate, the monomethyl ether (meth)acrylate of a copolymer of ethylene glycol and propylene glycol, N,N-dimethylaminoethyl (meth)acrylate, N,N-diethylaminoethyl (meth)acrylate, and N,N-dimethylaminopropyl (meth)acrylate.

Furthermore, a modified (meth)acrylic resin formed with a urethane group- or urea group-containing (meth)acrylic monomer may preferably be used.

Among these, from the viewpoint of aqueous ink resistance, an alkyl (meth)acrylate such as lauryl (meth)acrylate and an aliphatic cyclic structure-containing (meth)acrylate such as t-butylcyclohexyl (meth)acrylate are particularly preferable.

Among the specific polymers, from the viewpoint of printing durability, polyvinyl butyral and a derivative thereof are particularly preferable.

The content of the hydroxy group in the specific polymer in the present invention is preferably 0.1 to 15 mmol/g, and more preferably 0.5 to 7 mmol/g, for any of the above-mentioned polymer embodiments.

From the viewpoint of a good balance between shape retention of a coated film and developability, the content of Component A in the resin composition (relief-forming layer) that can be used in the present invention is preferably 2 to 95 wt % in the total solids content, more preferably 10 to 92 wt %, and yet more preferably 30 to 90 wt %.

It is preferable for the content of Component A to be in the above-mentioned range since shape retention of a coated film, ink laydown, and printing durability are satisfied with a good balance.

### (Component B) Photopolymerization Initiator

In the present invention, the relief-forming layer comprises (Component B) a photopolymerization initiator (hereinafter, also called a ‘polymerization initiator’). The polymerization initiator is a compound that generates a polymerization initiating species by absorbing external energy such as actinic radiation.

Component B generates a polymerization initiating species by exposure in the exposure step (irradiation with light, preferably actinic radiation, etc.), and causes polymerization of Component C, which is described later.

The polymerization initiator that can be used in the present invention is preferably a free-radical photoinitiator; examples thereof include an aromatic ketone (e.g. a quinone, an acetophenone compound, etc.), an acylphosphine compound, an aromatic onium salt compound, an organic peroxide, a thio compound, a hexaarylbiimidazole compound, a ketoxime ester compound, a borate compound, an azinium compound, a metallocene compound, an active ester compound, and a compound having a carbon-halogen bond. Specific examples of these polymerization initiators include polymerization initiators described in JP-A-2008-208190 and JP-A-2009-096985. With regard to the polymerization initiators, one type thereof may be used on its own or two or more types thereof may be used in combination.

In the present invention, it is preferable to use a hydrogen abstraction type photopolymerization initiator and a decomposition type photopolymerization initiator in combination.

It is preferable to use an aromatic ketone as the hydrogen abstraction type photopolymerization initiator. A chemical reaction mechanism is proposed in which an aromatic ketone attains an excited triplet state by light excitation with good efficiency and this excited triplet state abstracts a hydrogen from the surrounding medium to form a radical. The radical thus formed is thought to be involved in a photopolymerization reaction.

The hydrogen abstraction type photopolymerization initiator is not particularly limited as long as it is a compound that passes through an excited triplet state and forms a radical by abstracting a hydrogen from the surrounding medium. Examples thereof include a benzophenone, a Michler's ketone, a xanthene, a thioxanthone, and an anthraquinone, and it is preferable to use at least one type of compound selected from the above group. The benzophenone denotes benzophenone or a derivative thereof, and specific examples thereof include 3,3′,4,4′-benzophenonetetracarboxylic acid anhydride and 3,3′,4,4′-tetramethoxybenzophenone. The Michler's ketone denotes Michler's ketone or a derivative thereof. The xanthene denotes xanthene or an alkyl group-, phenyl group-, or halogen group-substituted derivative, and examples thereof include fluorescein, eosin, erythrosine, rhodamine B, and Rose Bengal. The thioxanthone denotes thioxanthone or an alkyl group-, phenyl group-, or halogen group-substituted derivative, and examples thereof include thioxanthone, 2-isopropylthioxanthone, 4-isopropylthioxanthone, ethylthioxanthone, methylthioxanthone, and chlorothioxanthone. The anthraquinone denotes anthraquinone or an alkyl group-, phenyl group-, or halogen group-, etc. substituted derivative.

The decomposition type photopolymerization initiator denotes a compound that undergoes a cleavage reaction in the molecule after absorbing light and forms an active radical, and is not particularly limited. Specific examples include a benzoin alkyl ether, a 2,2-dialkoxy-2-phenylacetophenone, an acetophenone, an acyloxime ester, an azo compound, an organic sulfur compound, and a diketone, and it is preferable to use at least one type of compound selected from the above group.

Examples of the benzoin alkyl ether include benzoin isopropyl ether, benzoin isobutyl ether, and compounds described in ‘Photosensitive Polymers’ (Kodansha, published in 1977, page 228). Examples of the 2,2-dialkoxy-2-phenylacetophenone include 2,2-dimethoxy-2-phenylacetophenone and 2,2-diethoxy-2-phenylacetophenone. Examples of the acetophenone include acetophenone, trichloroacetophenone, 1-hydroxycyclohexylphenylacetophenone, and 2,2-diethoxyacetophenone. Examples of the acyloxime ester include 1-phenyl-1,2-propanedione-2-(o-benzoyl)oxime. Examples of the azo compound include azobisisobutyronitrile, a diazonium compound, and a tetrazene compound. Examples of the organic sulfur compound include an aromatic thiol, mono- and di-sulfides, a thiuram sulfide, a dithiocarbamate, an S-acyldithiocarbamate, a thiosulfonate, a sulfoxide, a sulfenate, and a dithiocarbonate. Examples of the diketone include benzil and methylbenzoyl formate.

Furthermore, it is also possible to use as the photopolymerization initiator a compound having in the molecule both a moiety that functions as a hydrogen abstraction type photopolymerization initiator and a moiety that functions as a decomposition type photopolymerization initiator. Examples thereof include an α-aminoacetophenone. Specific examples include 2-methyl-1-(4-methylthiophenyl)-2-morpholinopropan-1-one and a compound represented by Formula (6) below.

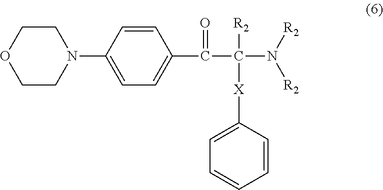

(In the Formula, R₂ mutually independently denote a hydrogen atom or an alkyl group having 1 to 10 carbons. X denotes an alkylene group having 1 to 10 carbons.)

With regard to Component B, one type thereof may be used on its own or two or more types thereof may be used in combination, and there are no particular limitations.

From the viewpoint of sufficient curing of an exposed portion and improving film strength, the content of Component B is preferably 0.01 to 10 wt % relative to the total solids content of the resin composition (relief-forming layer), more preferably 0.05 to 5 wt %, and yet more preferably 0.3 to 3 wt %.

Furthermore, the polymerization initiator may be used in combination with various types of sensitizer, and there are no particular limitations. The sensitizer that can be used in combination with the polymerization initiator is explained below.

### <Sensitizer>

Examples of the sensitizer include a polynuclear aromatic (e.g. pyrene, perylene, triphenylene, 2-ethyl-9,10-dimethoxyanthracene, etc.), a cyanine (e.g. thiacarbocyanine, oxacarbocyanine, etc.), a merocyanine (e.g. merocyanine, carbomerocyanine, etc.), a thiazine (e.g. thionine, methylene blue, toluidine blue, etc.), an acridine (e.g. acridine orange, chloroflavine, acriflavine, etc.), a squarium (e.g. squarium, etc.), and a coumarin (e.g. 7-diethylamino-4-methylcoumarin, etc.). Examples further include compounds described in paragraphs 0082 to 0115 of JP-A-2010-013574.

With regard to the sensitizer, one type thereof may be used on its own or two or more types thereof may be used in combination.

When a sensitizer is used, the total content of polymerization initiators relative to the content of the sensitizer is preferably 200:1 to 1:200 as a ratio by weight of polymerization initiator:sensitizer, more preferably 50:1 to 1:50, and yet more preferably 20:1 to 1:5.

(Component C) Ethylenically Unsaturated Compound Having Molecular Weight of No Greater than 3,000

In the present invention, the relief-forming layer comprises (Component C) an ethylenically unsaturated compound having a molecular weight of no greater than 3,000.

Component C undergoes polymerization upon irradiation with actinic radiation in the exposure step, and the exposed portion becomes resistant to melting by subsequent heating.

The molecular weight of Component C is no greater than 3,000. When the molecular weight of Component C exceeds 3,000, the resin composition becomes highly viscous, and it might become difficult to prepare a relief-forming layer. Furthermore, since melting during heating becomes insufficient and melt viscosity increases, it might become difficult to remove an unexposed portion in the development step.

Component C may be freely selected from compounds having at least one, preferably at least two, and more preferably 2 to 6 ethylenically unsaturated groups.

Furthermore, it is preferable for the Component C that can be used in the present invention to be a compound having at least 2 (preferably 2 to 6, more preferably 2 or 3, and yet more preferably 2) (meth)acrylic groups, and it is more preferable for it to be a compound having at least 2 (preferably 2 to 6, more preferably 2 or 3, and yet more preferably 2) (meth)acryloxy groups.

That is, Component C is preferably a 2- to 6-functional (meth)acrylate, more preferably a 2- or 3-functional (meth)acrylate, and yet more preferably a 2-functional (meth)acrylate.

Monofunctional polymerizable compounds having one ethylenically unsaturated double bond in the molecule and polyfunctional polymerizable compounds having two or more of said bond in the molecule, which are used as polymerizable compounds, are explained below.

Examples of the radically polymerizable ethylenically unsaturated compound include unsaturated carboxylic acids such as acrylic acid, methacrylic acid, itaconic acid, crotonic acid, isocrotonic acid, and maleic acid and salts thereof, an ethylenically unsaturated group-containing anhydride, a (meth)acrylate, a (meth)acrylamide, an acrylonitrile, a styrene, and various types of polymerizable compounds such as an unsaturated polyester resin, an unsaturated polyether resin, an unsaturated polyamide resin, and an unsaturated urethane resin.

In the present invention, ‘(meth)acrylate’ means ‘acrylate’ and/or ‘methacrylate’, and ‘(meth)acrylamide’ means ‘acrylamide’ and/or ‘methacryamide’.

Examples of the monofunctional polymerizable compound include acrylic acid derivatives such as methyl acrylate, ethyl acrylate, n-butyl acrylate, 2-ethylhexyl acrylate, 2-hydroxyethyl acrylate, butoxyethyl acrylate, carbitol acrylate, cyclohexyl acrylate, benzyl acrylate, N-methylolacrylamide, and epoxy acrylate, methacrylic acid derivatives such as methyl methacrylate, N-vinyl compounds such as N-vinylpyrrolidone and N-vinylcaprolactam, and allyl compounds such as allyl glycidyl ether, diallyl phthalate, and triallyl trimellitate.

Examples of the polyfunctional polymerizable compound include ester or amide compounds of an unsaturated carboxylic acid and a polyhydric alcohol compound or a polyvalent amine compound, such as ethylene glycol diacrylate, triethylene glycol diacrylate, propylene glycol diacrylate, triethylene glycol dimethacrylate, 1,3-butanediol diitaconate, pentaerythritol dicrotonate, sorbitol tetramalate, methylenebismethacrylamide, and 1,6-hexamethylenebisacrylamide, urethane acrylates described in JP-A-51-37193, polyester acrylates described in JP-A-48-64183, JP-B-49-43191 (JP-B denotes a Japanese examined patent application publication) and JP-B-52-30490, and a polyfunctional acrylate or methacrylate such as an epoxy (meth)acrylate formed by reaction of an epoxy resin and (meth)acrylic acid. Furthermore, radically polymerizable or crosslinkable monomers and oligomers that are commercial products or are industrially known, such as those described in Journal of the Adhesion Society of Japan, Vol. 20, No. 7, pp. 300 to 308 (1984); ‘Kakyozai Handobukku’ (Crosslinking Agent Handbook), Ed. S. Yamashita (Taiseisha, 1981); ‘UV•EB Koka Handobukku (Genryohen)’ (UV•EB Curing Handbook (Starting Materials)) Ed. K. Kato (Kobunshi Kankoukai, 1985); ‘UV•EB Koka Gijutsu no Oyo to Shijyo’ (Application and Market of UV•EB Curing Technology), p. 79, Ed. RadTech (CMC, 1989); and E. Takiyama ‘Poriesuteru Jushi Handobukku’ (Polyester Resin Handbook), (The Nikkan Kogyo Shimbun Ltd., 1988) may be used.

Since a preferred mode of the relief-forming layer related to the present invention is one in which a crosslinked structure can be formed in the film, a polyfunctional polymerizable compound is preferably used. The molecular weight of the polyfunctional polymerizable compounds is preferably 200 to 2,000.

In the present invention, an oligomer may be used as Component C.

An oligomer is generally a polymer in which a limited number (usually 5 to 100) of monomers are bonded, and known compounds called oligomers may be selected freely, but in the present invention it is preferable to select a polymer having a weight-average molecular weight of 400 to 3,000 (more preferably 500 to 3,000).

The oligomer has an ethylenically unsaturated group, and more preferably has a (meth)acryloxy group.

The oligomer in the present invention may be any oligomer, and examples thereof include an olefin-based oligomer (an ethylene oligomer, a propylene oligomer, a butene oligomer, etc.), a vinyl-based oligomer (a styrene oligomer, a vinyl alcohol oligomer, a vinylpyrrolidone oligomer, an acrylate oligomer, a methacrylate oligomer, etc.), a diene-based oligomer (a butadiene oligomer, a chloroprene rubber, a pentadiene oligomer, etc.), a ring-opening polymerization type oligomer (di-, tri-, tetra-ethylene glycol, polyethylene glycol, polyethylimine, etc.), an addition-polymerization type oligomer (an oligoester acrylate, a polyamide oligomer, a polyisocyanate oligomer), and an addition-condensation oligomer (a phenolic resin, an amino resin, a xylene resin, a ketone resin, etc.). Among them an oligoester (meth)acrylate is preferable, and among them a urethane (meth)acrylate, a polyester (meth)acrylate, and an epoxy (meth)acrylate are preferable, and a urethane (meth)acrylate is more preferable.

As the urethane (meth)acrylate, an aliphatic urethane (meth)acrylate and an aromatic urethane (meth)acrylate may preferably be cited, and an aliphatic urethane (meth)acrylate may more preferably be cited.

Furthermore, the urethane (meth)acrylate is preferably a tetra- or lower-functional urethane (meth)acrylate, and more preferably a di- or lower-functional urethane (meth)acrylate. In accordance with a urethane (meth)acrylate being contained, a relief-forming layer having excellent curability can be obtained.

With respect to the oligomer, ‘Origomar Handobukku (Oligomer Handbook)’ (edited by Junji Furukawa, The Chemical Daily Co., Ltd.) may also be referred to.

The oligomer is also available as a commercial product, and examples thereof are shown below. Among these, one having a molecular weight of no greater than 3,000 may be used as Component C.

Examples of urethane (meth)acrylates include R1204, R1211, R1213, R1217, R1218, R1301, R1302, R1303, R1304, R1306, R1308, R1901, and R1150 manufactured by Dai-Ichi Kogyo Seiyaku Co., Ltd., the EBECRYL series (e.g. EBECRYL 230, 270, 4858, 8402, 8804, 8807, 8803, 9260, 1290, 1290K, 5129, 4842, 8210, 210, 4827, 6700, 4450, and 220) manufactured by Daicel-Cytec Company Ltd., NK Oligo U-4HA, U-6HA, U-15HA, U-108A, and U200AX manufactured by Shin-Nakamura Chemical Co., Ltd., and Aronix M-1100, M-1200, M-1210, M-1310, M-1600, and M-1960 manufactured by Toagosei Co., Ltd.

Examples of polyester (meth)acrylates include the EBECRYL series (e.g. EBECRY L770, IRR467, 81, 84, 83, 80, 675, 800, 810, 812, 1657, 1810, IRR302, 450, 670, 830, 870, 1830, 1870, 2870, IRR267, 813, IRR483, 811, etc.) manufactured by Daicel-Cytec Company Ltd. and Aronix M-6100, M-6200, M-6250, M-6500, M-7100, M-8030, M-8060, M-8100, M-8530, M-8560, and M-9050 manufactured by Toagosei Co., Ltd.

Examples of epoxy (meth)acrylates include the EBECRYL series (e.g. EBECRYL 600, 860, 2958, 3411, 3600, 3605, 3700, 3701, 3703, 3702, 3708, RDX63182, 6040, etc.) manufactured by Daicel-Cytec Company Ltd.

In the present invention, with regard to Component C, one type thereof may be used on its own or two or more types thereof may be used in combination. The content of Component C in the relief-forming layer is preferably 3 to 80 wt %, more preferably 5 to 70 wt %, and yet more preferably 10 to 60 wt %. From the viewpoint of improvement of printing durability and suppression of tackiness of the film surface, it is preferable for the content of Component C to be in the above-mentioned range.

### (Component D) Plasticizer

From the viewpoint of imparting the flexibility required as a flexographic printing plate, it is preferable in the present invention for the relief-forming layer to comprise (Component D) a plasticizer. The plasticizer has the function of softening a film that is formed and is required to be compatible with Component A.

A plasticizer known as a polymer plasticizer may be used without limitations; examples thereof include, as described in pp. 211 to 220 of ‘Kobunshi Daijiten (Polymer Dictionary)’ (first edition, 1994, Maruzen Co., Ltd.), an adipic acid derivative, an azelaic acid derivative, a benzoylic acid derivative, a citric acid derivative, an epoxy derivative, a glycol derivative, a hydrocarbon and a derivative thereof, an oleic acid derivative, a phosphoric acid derivative, a phthalic acid derivative, a polyester type, a polyetherester type, a ricinoleic acid derivative, a sebacic acid derivative, a stearic acid derivative, a sulfonic acid derivative, a terpene and a derivative thereof, and a trimellitic acid derivative, and from the viewpoint of the large ability of reducing a glass transition temperature, an adipic acid derivative, a citric acid derivative, and a phosphoric acid derivative are preferable.

The adipic acid derivative is preferably dibutyl adipate or 2-butoxyethyl adipate, and the citric acid derivative is preferably tributyl citrate. Examples of the phosphoric acid derivative include tributyl phosphate, tri-2-ethylhexyl phosphate, tributoxyethyl phosphate, triphenyl phosphate, cresyldiphenyl phosphate, tricresyl phosphate, t-butylphenyl phosphate, and 2-ethylhexyldiphenyl phosphate, and among them triphenyl phosphate, cresyldiphenyl phosphate, and tricresyl phosphate are preferable, and cresyldiphenyl phosphate is more preferable.

Furthermore, as the plasticizer, for example, dioctyl phthalate, didodecyl phthalate, a polyethylene glycol, a polypropylene glycol (monool type or diol type), trimethylolpropane, etc. are also preferably used. Examples further include a liquid long-chain hydrocarbon having a reactive site (e.g. an ethylenically unsaturated bond). Specific examples thereof include oleyl alcohol, liquid polyisoprene, and liquid polyisobutadiene.

As the plasticizer, it is preferable to use an inert plasticizer, and the inert plasticizer means the plasticizer having no polymerizable group, or substantially having no polmerizable group. Examples of suitable inert plasticizers include in particular alkyl esters of alkanecarboxylic acids, in particular alkanedicarboxylic acids, arylcarboxylic acids or phosphoric acid. Preferred alcoholic components of the esters are straight-chain or branched C₈ to C₂₀-alkanols, particularly preferably C₈ to C₁₃-alkanols, such as n-octanol, 2-ethylhexanol, n-nonanol, isononanol, n-decanol, isodecanol, n-undecanol, isoundecanol, n-dodecanol, isododecanol, n-tridecanol and isotridecanol. The term “iso”alkanols is understood in the case of said compounds as meaning a mixture of different isomers which are usually obtained in the industrial synthesis of the alkanols. Preferred carboxylic components in the esters are in particular alkanedicarboxylic acids of at least 6 carbon atoms, for example adipic acid, azelaic acid, sebacic acid and phthalic acid. Suitable diesters may be both symmetrical esters and those which have two different alcoholic groups. Examples of ester-based inert plasticizers include di-2-ethylhexyl phthalate, di-2-ethylhexyl adipate, diisononyl adipate, diisodecyl phthalate, diisoundecyl phthalate, undecyl dodecyl phthalate, ditridecyl phthalate and ditridecyl adipate.

Further examples of inert plasticizers include high-boiling paraffinic, naphthenic and aromatic mineral oils. Such mineral oils are obtained by distillation of mineral oils under reduced pressure.

High-boiling substantially paraffinic and/or naphthenic mineral oils are preferable. Such mineral oils are also referred to as white oils, a person skilled in the art distinguishing between technical-grade white oils which can still have a low content of aromatics, and medical white oils, which are substantially free of aromatics. They are commercially available, for example Shell Risella (technical-grade white oil) or Shell Ondina (medical white oil).

As the plasticizer a commercial product may be used, and examples thereof include the Adekaizer RS series (ADEKA).

In the present invention, as the plasticizer, a citric acid derivative, a polyethylene glycol, or a polypropylene glycol is preferably used. In particular, when a polyvinyl butyral derivative is used as Component A, it is preferable to use the above-mentioned plasticizer.

Examples of the citric acid derivative include tributyl citrate, 2-ethylhexyl citrate, hydroxyethyl citrate, and hexyl citrate.

Examples of the polyethylene glycol include diethylene glycol, triethylene glycol, tetraethylene glycol, a polyethylene glycol that has a degree of polymerization of ethylene oxide of at least 5, polyethylene glycol monomethyl ether, and polyethylene glycol dimethyl ether.

Examples of the polypropylene glycol include dipropylene glycol, tripropylene glycol, tetrapropylene glycol, polypropylene glycol monomethyl ether, and polypropylene glycol dimethyl ether.

In the present invention, with regard to Component D, one type may be used on its own or two or more types thereof may be used in combination. From the viewpoint of printing durability and developability, the content of Component D in the resin composition (relief-forming layer) of the present invention is preferably 1 to 30 wt % on a solids content basis, more preferably 5 to 25 wt %, and yet more preferably 10 to 20 wt %.

### <Other Additive>

In the present invention the relief-forming layer may contain, as appropriate and in a range that does not inhibit the effects of the present invention, an additive other than Component A to Component D above. The total amount of Components A to D is preferably at least 60 wt % of the relief-forming layer on a solids content basis, more preferably at least 80 wt %, and yet more preferably at least 95 wt %.

Examples of the additive include a fragrance, a filler, a wax, a process oil, an organic acid, a metal oxide, an ozone decomposition inhibitor, an antioxidant, a thermopolymerization inhibitor, and a colorant; one type thereof may be used on its own or two or more types thereof may be used in combination.

Furthermore, the use of a co-sensitizer enables the sensitivity when photocuring the relief-forming layer to be further improved.

Moreover, it is preferable to add a small amount of a thermopolymerization inhibitor in order to inhibit unwanted thermopolymerization of a polymerizable compound during production or storage of the composition.

For the purpose of coloring the relief-forming layer, a colorant such as a dye or a pigment may be added. This enables properties such as visibility of an image area and suitability for an image densitometer to be improved.

Furthermore, a known additive such as a filler for improving physical properties of a cured film may be added.

These additives may be incorporated into a polymer formed by polymerization of Component C by a curing reaction or may be present without being incorporated into the polymer.

### (Layer Structure)

The flexographic printing plate precursor for thermal development of the present invention comprises a relief-forming layer comprising at least Component A to Component C. The relief-forming layer is preferably provided on/above a support.

The flexographic printing plate precursor may further comprise an adhesive layer between the support and the relief-forming layer as necessary, and may comprise a slip coat layer or a protection film above the relief-forming layer.

### <Relief-Forming Layer>

The relief-forming layer is a layer comprising at least Component A to Component C and is a curable layer.

The relief-forming layer may be formed by molding a resin composition comprising the above-mentioned components for the relief-forming layer into a sheet shape or a sleeve shape. The relief-forming layer is normally provided on/above a support, which is described later, but may be immobilized by directly forming or placing it on the surface of a member such as a cylinder of an apparatus for plate making or printing, and a support is not always required.

From the viewpoint of storage stability, the relief-forming layer preferably does not have flowability at normal temperature. When the relief-forming layer has excessive flowability at normal temperature, nonuniformity occurs in the thickness of the relief-forming layer due to flow, and it is not suitable for use.

A case in which the relief-forming layer is formed mainly into a sheet shape is explained as an example.

### <Support>

A material used for the support of the flexographic printing plate precursor is not particularly limited, but one having high dimensional stability is preferably used, and examples thereof include metals such as steel, stainless steel, or aluminum, plastic resins such as a polyester (e.g. PET (polyethylene terephthalate), PBT (polybutylene terephthalate), PAN (polyacrylonitrile)), polyvinyl chloride, polycarbonate, or polyimide, synthetic rubbers such as styrene-butadiene rubber, and glass fiber-reinforced plastic resins (epoxy resin, phenolic resin, etc.). As the support, a PET film or a steel substrate is preferably used. The configuration of the support depends on whether the relief-forming layer is in a sheet shape or a sleeve shape.

### <Adhesive Layer>

When the relief-forming layer is formed above a support, an adhesive layer may be provided between the two for the purpose of strengthening the adhesive power between the layers.

It is preferable that by carrying out an undercoating treatment or an adhesion promoting treatment the resulting adhesive layer strengthens the adhesive or joining power of the relief-forming layer and the relief layer toward the support. Such treatments are generally carried out for the surface of the support before coating of the relief-forming layer.

A corona discharge treatment, a laser treatment described in U.S. Pat. No. 4,822,451, a surface mechanical roughening treatment, a coating treatment with a chemical undercoat agent, etc. may be employed

As a material (adhesive) that can be used in the adhesive layer, for example, those described in ‘Handbook of Adhesives’, Ed. by I. Skeist, 2^{nd} Edition (1977) may be used.

### <Protection Film, Slip Coat Layer>

For the purpose of preventing scratches or dents in the relief-forming layer surface, a protection film may be provided on/above the relief-forming layer surface. The thickness of the protection film is preferably 25 to 500 μm, and more preferably 50 to 200 μm. The protection film may employ, for example, a polyester-based film such as PET or a polyolefin-based film such as PE (polyethylene) or PP (polypropylene). The surface of the film may be made matte. The protection film is preferably peelable.

When the protection film is not peelable or conversely has poor adhesion to the relief-forming layer, a slip coat layer may be provided between the two layers. The material used in the slip coat layer preferably employs as a main component a resin that is soluble or dispersible in water and has little tackiness, such as polyvinyl alcohol, polyvinyl acetate, partially saponified polyvinyl alcohol, a hydroxyalkylcellulose, an alkylcellulose, or a polyamide resin.

### (Process for Producing Flexographic Printing Plate Precursor)

Formation of a relief-forming layer in the flexographic printing plate precursor for thermal development is not particularly limited, and examples thereof include a method in which the resin composition for coating containing at least Component A to Component C is prepared, solvent is removed as necessary from this resin composition for coating, and it is melt-extruded onto a support. Alternatively, a method may be employed in which the resin composition is cast onto a support, and this is dried in an oven to thus remove solvent from the resin composition.

Subsequently, as necessary, a protection film may be laminated on the relief-forming layer. Laminating may be carried out by compression-bonding the protection film and the relief-forming layer by means of heated calendar rollers, etc. or putting a protection film into intimate contact with a relief-forming layer whose surface is impregnated with a small amount of solvent.

When a protection film is used, a method in which a relief-forming layer is first layered on a protection film and a support is then laminated may be employed.

When an adhesive layer is provided, it may be dealt with by use of a support coated with an adhesive layer. When a slip coat layer is provided, it may be dealt with by use of a protection film coated with a slip coat layer.

### <Layer Formation Step>

In the present invention, the process for making the flexographic printing plate precursor preferably comprises a layer formation step of forming a relief-forming layer from the resin composition comprising at least Component A to Component C.

Preferred examples of a method for forming a relief-forming layer include a method in which the resin composition comprising Component A to Component C is prepared, solvent is removed as necessary from this resin composition, and it is then melt-extruded onto a support and a method in which the resin composition comprising Component A to Component C is prepared, the resin composition is cast onto a support, and this is dried in an oven to thus remove the solvent.

The resin composition may be preferably produced by, for example, dissolving Component A to Component C, and as optional Component D, etc. to an appropriate solvent.

From the viewpoint of a balance between development speed and printing durability, the thickness of the relief-forming layer in the flexographic printing plate precursor for thermal development is preferably at least 0.1 mm but no greater than 10 mm, more preferably at least 0.2 mm but no greater than 7 mm, and yet more preferably at least 0.3 mm but no greater than 3 mm.

### (Flexographic Printing Plate and Process for Making Same)

The process for making a flexographic printing plate of the present invention preferably comprises (Step a) an exposure step of imagewise exposing a relief-forming layer of a flexographic printing plate precursor, (Step b) a heating step of heating the exposed flexographic printing plate precursor at a temperature of 40° C. to 270° C., and (Step c) a development step of removing an unexposed portion that has become softened by heating, and it more preferably comprises, prior to Step a above, a layer formation step of forming a relief-forming layer and a backside irradiation step of irradiating the backside of the relief-forming layer.

The flexographic printing plate of the present invention is a flexographic printing plate obtained by exposing and developing the flexographic printing plate precursor for thermal development of the present invention, and preferably a flexographic printing plate made by the process for making a flexographic printing plate of the present invention.

The flexographic printing plate of the present invention may suitably be used when printing using an aqueous ink or a solvent ink.

### <Backside Irradiation Step>

In the present invention, the flexographic printing plate precursor is preferably subjected to a backside irradiation step prior to Step a. The backside irradiation step is a step of irradiating the relief-forming layer by applying actinic radiation toward the support and making it pass through the support using an actinic radiation irradiation source provided adjacent to the support side across a distance.

Backside irradiation causes partial curing of the relief-forming layer. This curing progresses more in a section closer to the support, and in the surface layer (furthest from the support) the curing level is the lowest.

The backside irradiation step is preferably carried out for a shorter time than (Step a) the exposure step, which is carried out subsequent thereto, and the backside irradiation step is not carried out under irradiation conditions (exposure intensity, exposure time) that cure the entire relief-forming layer.

In the backside irradiation step, it is preferable to apply an electron beam, and the electron beam is applied toward the support at an energy that does not completely pass through by the relief-forming layer.

It is preferable to adjust irradiation conditions so that less than 75% of the actinic radiation applied passes through a thickness of 50% of the relief-forming layer. The section where curing progresses the most is the interfacial section between the relief-forming layer and the support, and curing is incomplete on the outside face (face opposite to the support) of the relief-forming layer.

When carrying out electron beam irradiation, by adjusting the potential energy with which accelerated electrons pass through, the distance of electrons passing through the support and the relief-forming layer can be controlled.

The backside irradiation step allows a relatively thin continuous layer of cured relief-forming layer strongly joined onto the support to be formed. This thin cured layer (floor) becomes a foundation or support surface for an image portion that is formed later. In particular, with regard to fine parts of an image, this thin cured layer physically reinforces the adhesion of fine parts, suppresses the loss thereof from the support due to abrasion or poor curing, and improves printing durability.

The thin cured layer (floor) formed in the backside irradiation step is not removed from the support even by development.

### <(Step a) Exposure Step of Imagewise Exposing Relief-Forming Layer of Flexographic Printing Plate Precursor>

The process for making a flexographic printing plate of the present invention preferably comprises (Step a) an exposure step of imagewise exposing a relief-forming layer of a flexographic printing plate precursor. The exposure step is preferably a step of curing an exposed portion of the relief-forming layer by crosslinking and/or polymerization.

The exposure step is preferably carried out by irradiating the relief-forming layer with actinic radiation through a negative mask provided above the relief-forming layer.

A vacuum frame irradiator is suitable for such exposure.

The vacuum frame irradiator evacuates air between the relief-forming layer and a negative mask and subsequently irradiates the relief-forming layer with actinic radiation for an exposure time that is sufficient for making a cured layer (relief layer) suitable for conditions under which the flexographic printing plate is used.

In the present invention, the exposure step is not limited to the above, and it may be selected appropriately from known steps.

The actinic radiation used in the backside irradiation step and the exposure step is radiation that can provide energy that enables an initiating species to be generated in the relief-forming layer when irradiated, and includes α rays, α rays, X rays, UV, visible light, and an electron beam. Among these, UV and an electron beam are preferable from the viewpoint of curing sensitivity and the availability of equipment, and the use of UV is more preferable in the exposure step.

Furthermore, examples of the source for actinic radiation include a low-pressure mercury lamp, a high-pressure mercury lamp, a metal halide lamp, a carbon arc lamp, a xenon lamp, a zirconium lamp, and sunlight. It is also possible to use an LED or an LD as the actinic radiation source.

In the exposure step, it is preferable to apply UV.

The wavelength of actinic radiation applied, the output of the actinic radiation applied, the exposure area illumination intensity, and the exposure time are not particularly limited and it is preferable to select them appropriately from the viewpoint of curability and productivity.

<(Step b) Heating Step of Heating Exposed Flexographic Printing Plate Precursor to Temperature of 40° C. to 270° C. and (Step c) Step of Removing Unexposed Portion that has Become Softened by Heating>

After the relief-forming layer is imagewise exposed, development is carried out by removing an uncured portion of the relief-forming layer.

Step b and Step c above may be carried out at the same time.

In addition, Step c preferably comprises a step of removing an unexposed portion of the relief-forming layer that has become softened by heating by making the unexposed portion adhere to an absorbent member.

It is preferable to use an absorbent member (hereinafter, also called an absorbing material) for removal of the uncured portion. It is preferable that, after the exposure step, the negative mask is removed from the relief-forming layer, and instead of the negative mask the absorbent member is placed above the relief-forming layer.

Uncured relief-forming layer is melted by heating in Step b. It is preferable to contact this molten relief-forming layer with the absorbent member, thereby making the uncured relief-forming layer transfer to the absorbent member. Furthermore, separating the absorbing material in a heated state from the relief-forming layer allows a relief structure to be developed, giving a relief layer. The flexographic printing plate is cooled to room temperature, then mounted on a printing plate cylinder, etc., and used for printing.

The absorbent member may be placed above the relief-forming layer at the same time as the heating step or may be placed above the relief-forming layer prior to heating. Furthermore, the absorbent member may be placed in a state in which softening of an unexposed portion of the relief-forming layer has proceeded to some extent, without particular limitation.

The absorbent member that is used for removing uncured relief-forming layer from the exposed flexographic printing plate precursor is preferably a sheet-shaped member, and is preferably a material that has internal strength and tear resistance at a temperature at which the uncured relief-forming layer melts and that has high absorption of the molten uncured relief-forming layer. That is, it is necessary that the melting or softening temperature of the absorbent member used is higher than the melting or softening temperature of uncured relief-forming layer. Absorption is measured by the number of grams of uncured relief-forming layer that can be absorbed by 1 mL of the absorbent member.

The absorbent member is preferably selected from a nonwoven material, a paper material, a fiber woven fabric material, an open-cell foam material, a porous sheet, or another sheet material having voids.

Preferred examples of the absorbent member include blown microfiber non-woven web materials produced from high temperature melting polymeric materials such as polypropylene, polyester, nylon or other high temperature melting thermoplastic polymers. Additional examples of the absorbent member that can be used in the present invention include absorbent stocks produced by various paper making processes. Open-celled thermoset foams are also acceptable.

Preferred absorbent members contain a void volume fraction of at least 50% of the included volume of the sheet (as measured in the uncompressed condition).

More preferred examples of the absorbent member include spun-bonded nylon non-woven webs such as CEREX™ non-woven webs produced by the James River Corporation. Inorganic filament webs, particularly those with porous filaments, may also be used.

With regard to absorption of uncured relief-forming layer by the absorbent member, the term ‘absorption’ does not particularly restrict the absorption phenomenon. It is unnecessary for the molten uncured relief-forming layer to penetrate into the body of fibers, filaments, microparticles, etc. forming the absorbent member, and absorption onto the absorbent member may be occurred only by surface wetting of an internal portion.

The driving force by which molten uncured relief-forming layer is moved to the absorbent member is not particularly limited, and examples thereof include surface tension, electrical force (e.g. van der Waals force), polar attractive force, affinity, and another physical force.

The heating temperature in Step b is not particularly limited and may be selected appropriately from a range of temperatures at which an unexposed portion of the relief-forming layer melts and/or softens and transfers to the absorbent member by contacting the absorbent member and at which an exposed portion (cured portion) of the relief-forming layer does not melt and/or soften.

From the viewpoint of productivity and ease of handling, the heating temperature is preferably 40° C. to 270° C., more preferably 60° C. to 250° C., and yet more preferably 70° C. to 230° C. In the present invention, use of a polymer having a glass transition temperature of at least 25° C. as Component A, that is, a non-elastomer, enables melting and/or softening of a cured portion of the relief-forming layer by the above-mentioned heating to be suppressed, and the relief shape obtained is sharp.

In Step c, it is preferable that at least 75 wt % of the unexposed portion of the relief-forming layer is removed, and it is more preferable that it is removed by absorption by the absorbent member. It is more preferable that at least 80 wt % thereof is removed, and it is yet more preferable that at least 85 wt % is removed. When there is the backside irradiation step, a thin continuous layer (floor) cured in the backside irradiation step is not included in the unexposed portion that is to be removed.

It is preferable for at least 75 wt % of the unexposed portion to be removed since a good relief shape is obtained.

In the present invention, a post-curing step of further curing the relief-forming layer may be added as necessary. Carrying out the post-curing step, which is an additional curing step, enables a relief formed by exposure to become stronger.

As hereinbefore described, a flexographic printing plate having a relief layer above the surface of any substrate, such as a support, is obtained.

From the viewpoint of satisfying various aspects of printing suitability, such as abrasion resistance and ink transfer properties, the thickness of the relief layer of the flexographic printing plate is preferably at least 0.1 mm but no greater than 10 mm, more preferably at least 0.2 mm but no greater than 7 mm, and yet more preferably at least 0.3 mm but no greater than 3 mm.

Furthermore, the Shore A hardness of the relief layer of the flexographic printing plate is preferably at least 50° but no greater than 90°. When the Shore A hardness of the relief layer is at least 50°, even if fine halftone dots formed by engraving receive a strong printing pressure from a letterpress printer, they do not collapse and close up, and normal printing can be carried out. Furthermore, when the Shore A hardness of the relief layer is no greater than 90°, even for flexographic printing with kiss touch printing pressure it is possible to prevent patchy printing in a solid printed part.

The Shore A hardness in the present specification is a value measured by a durometer (a spring type rubber hardness meter) that presses an indenter (called a pressing needle or indenter) into the surface of a measurement target at 25° C. so as to deform it, measures the amount of deformation (indentation depth), and converts it into a numerical value.

The flexographic printing plate of the present invention is particularly suitable for printing by a flexographic printer using an aqueous ink, but printing is also possible when it is carried out by a letterpress printer using any of aqueous, oil-based, and UV inks, and printing is also possible when it is carried out by a flexographic printer using a UV ink. The flexographic printing plate of the present invention has excellent laydown properties and printing durability, and printing can be carried out for a long period of time without plastic deformation of the relief layer or degradation of printing durability.

In accordance with the present invention, there can be provided a flexographic printing plate precursor for thermal development that has excellent thermal developability and gives a flexographic printing plate having excellent printing durability. There can also be provided a process for making a flexographic printing plate employing the flexographic printing plate precursor for thermal development, and a flexographic printing plate obtained thereby.

### EXAMPLES

The present invention is explained below further in detail by reference to Examples.

The weight-average molecular weight (Mw) of polymers in the Examples is expressed as a value measured by a gel permeation chromatography (GPC) method unless otherwise specified. Furthermore, ‘parts’ denotes ‘parts by weight’ and ‘%’ denotes ‘weight %’ unless otherwise specified.

The components used in the Examples were as follows.

### (Component A)

S-LEC BL-1H: polyvinyl butyral, Tg 63° C., Sekisui Chemical Co., Ltd.
S-LEC BM-2: polyvinyl butyral, Tg 67° C., Sekisui Chemical Co., Ltd.
S-LEC BL-S: polyvinyl butyral, Tg 61° C., Sekisui Chemical Co., Ltd.
S-LEC BM-S: polyvinyl butyral, Tg 61° C., Sekisui Chemical Co., Ltd.
Mowital B60H: polyvinyl butyral (m=1 to 4, n=18 to 21), Tg 68° C., Kuraray Co., Ltd.
Mowital B30HH: polyvinyl butyral (m=1 to 4, n=11 to 14), Tg 60° C., Kuraray Co., Ltd.
Kuraray Poval PVA205: polyvinyl alcohol (degree of saponification 86.5% to 89.0%, degree of polymerization 500), Tg 85° C., Kuraray Co., Ltd.
Gohsenal T330H: anionized polyvinyl alcohol (polyvinyl alcohol having carboxy group in side chain), Tg 80° C., The Nippon Synthetic Chemical Industry Co., Ltd.
Vylon UR-1350: polyester urethane resin, Tg 46° C., Toyobo Co., Ltd.
Vylon 220: amorphous polyester resin, Tg 53° C., Toyobo Co., Ltd.
Vylon 226: amorphous polyester resin, Tg 65° C., Toyobo Co., Ltd.
Vyloecol BE-400: amorphous polylactic acid resin (Mn 43,000), Tg 50° C., Toyobo Co., Ltd.
Polymethyl methacrylate: Tg 110° C., Aldrich
Marproof G-0150M: (meth)acrylic resin, Tg 71° C., NOF Corporation

### Polycarbonate: Tg 147° C., Aldrich

Metolose SM: methylcellulose, Tg 100° C., Shin-Etsu Chemical Co., Ltd.
Metolose 60SH: methylcellulose, Tg 100° C., Shin-Etsu Chemical Co., Ltd.
TR-2000: synthetic rubber (SBR), Tg −78° C., 100° C., JSR
Polyurethane elastomer A: synthesized by method below

### <Synthesis of Polyurethane Elastomer A>

The components shown below were mixed completely until uniform in a feed tank, thus preparing a polyol mixture.

Poly-1,2-(butylene oxide) diol having molecular weight of 1,000 (Dow Chemical): 286.1 parts (0.2861 mole)
1,4-Butanediol (GAF Chemical): 32.8 parts (0.3644 mole)
2-Glycerol methacrylate (3M): 10.7 parts (0.0669 mole)
Diethoxyacetophenone (Irgacure 651, Ciba-Geigy Ltd.): 10.6 parts
Methylene blue: 0.1 parts
Iron (III) chloride: 0.06 parts
Dibutyltin dilaurate: 0.26 parts

62.47 parts by weight of the polyol stream and 37.53 parts by weight of 4,4′-bis(isocyanatocyclohexyl)methane (Desmodur W (registered trademark), Mobay Chemical) were charged at this ratio into an inlet of a 64 mm twin-screw counter rotating extruder (Leistritz) using a high precision flowmeter. For this ratio by weight, the amount of isocyanate moiety charged was slightly in excess relative to the amount of hydroxy moiety charged. By keeping the reaction temperature at 150° C. to 170° C. polymerization proceeded in the extruder. A completely reacted curable elastomer composition was discharged from the extruder, cut into pellets having a diameter of about 0.3 cm, and collected for further treatment. Termination of polymerization was determined by measuring the absorption ratio of an —NCO absorption band (2,250 cm⁻¹) relative to a —CH₂— absorption band (2,950 cm⁻¹) by monitoring a cast film of the curable elastomer composition using an infrared spectrometer. It showed termination of the reaction in which a slight excess of —NCO groups remained at a proportion that was less than 0.2. A heating chamber of an extrusion plastometer was charged with 1,100 g of the sample, and the melt index of this curable elastomer composition was monitored at 153° C. It was found that it was in a range of 10 to 20 g for a 10 minute interval.

The structure of polyurethane elastomer A had the following molar ratio.

Molar ratio=4,4′-bis(isocyanatocyclohexyl)methane 2.730:1,4-butanediol 1.274:2-glycerol methacrylate 0.234:poly-1,2-(butylene oxide)diol 1.000

### (Component B)

Irgacure 184: 1-hydroxycyclohexyl phenyl ketone, BASF

### (Component C)

Blemmer PDE-100: diethylene glycol dimethacrylate (molecular weight: 242.27), NOF Corporation
Blemmer PDE-400: polyethylene glycol dimethacrylate (molecular weight: 550.64), NOF Corporation
Blemmer PDBE-450: ethoxylated bisphenol A dimethacrylate (molecular weight: 804.96), NOF Corporation
EBECRYL 230: urethane acrylate (molecular weight 5,000, number of functional groups 2), Daicel-Cytec Company Ltd.

### (Component D)

ADK Cizer RS-540: polyether ester-based plasticizer, ADEKA
Diethylene glycol
Tributyl citrate: Wako Pure Chemical Industries, Ltd.

### Example 1

The resin composition comprising Component A to Component D was reextruded into a flexographic printing plate construction utilizing a 125 mm single screw extrusion device as follows.

The resin composition (Component A: 50 parts, Component B: 0.5 parts, Component C: 30 parts, Component D: 20 parts) was charged into the feed hopper of the extruder. The temperatures of the heated zones of the extruder were maintained between 130° C. and 160° C. during the experiment. A film extrusion die was utilized at the exit of the extruder to allow casting of the extrudate onto a polyethylene terephthalate film base of 0.18 mm thickness to form the relief-forming layer of the flexographic printing plate precursor.

Prior to beginning the extrusion step, the major portion of the film base had been coated with a priming composition comprising a tris-aziridine compound (as disclosed in EPO Publication 0 206 669) to enhance adhesion of the relief-forming layer.

The extrudate was introduced into a controlled orifice gap consisting of two rotating chill rolls maintained at 20° C. to 25° C. An unprimed top film of polyethylene terephthalate of 0.08 mm thickness was introduced into this gap also to serve as a protective film over the curable relief-forming layer prior to formation of the flexographic printing plate.

A continuous roll of flexographic printing plate precursor having plural layers of thickness 0.66 mm was thus produced having a curable relief-forming layer of thickness 0.4 mm in combination with a support sheet of polyethylene terephthalate film of 0.18 mm thickness and a removable top film of 0.08 mm thickness.

One-meter long sections of the multi-layered product described above were backside exposed by using an Electrocurtain™ electron beam irradiation device (product of Energy Sciences, Inc.) as follows. The accelerating potential of the electrons emanating from the unit was preset to 240 KeV. The printing plate precursor was exposed to the electron beam energy in an orientation so that the beam energy was directed toward the printing plate precursor from the 0.4 mm polyester film support side. In this manner, the portion of the relief-forming layer in contact with the primed polyester film base received the greatest irradiation energy.

The energy dose was controlled so that the product received an absorbed dose of 5 Mrad as measured at the point at which the beam entered the product surface. This exposure step was accomplished over the entire product area so as to partially cure a portion of the relief-forming layer, particularly that portion in direct contact with the polyester support base.

An imagewise exposure of the relief-forming layer was next accomplished as follows. The polyester top film (0.08 mm) was removed from the relief-forming layer. A thin coating of a water dispersed urethane resin which contained small beads of silicon dioxide of approximately 20 μm in diameter was applied to the exposed surface of the relief-forming layer and allowed to air dry for a few minutes. A silver halide photographic exposure negative (of the type in common use in the graphic arts industry) which contained picture information in the form of the magenta separation obtained from a 35 mm photographic slide of a crown (which separation was produced utilizing a film scanner (Hell Corporation) at 52.4 line screen per inch definition) was placed in contact with the silicon dioxide coated side of the relief-forming layer. This multi-layered laminated body was placed in the vacuum exposure frame contained in a Kelleigh flexographic plate processor (Model #210). The top film attached to the exposure frame was drawn over the laminated body, vacuum was applied, and the air was exhausted between the exposure negative and the surface of the relief-forming layer. Ultraviolet light exposure of the plate through the photographic negative was then performed for a 6 minute period, after which the evacuation was terminated, and the exposure negative removed.

A visible image was formed in the UV exposed areas of the relief-forming layer (photobleaching had occurred which rendered the exposed areas transparent and a light yellow color) while the unexposed areas remained light blue in color. Removal of the unexposed and uncured areas of the relief-forming layer (to complete the manufacture of a flexographic printing plate) was next accomplished as follows.

Sections of non-woven spun-bonded nylon porous web (CEREX™ spunbonded nylon, a product of James River Corp.) of basis weight 66 grams/square meter were cut in size to match the area of the printing plate to be processed. A layer of the non-woven web was placed in contact with the relief-forming layer of the exposed printing plate. The laminate was placed on a heated platten equilibrated to 135° C. with the polyester film surface of the printing plate in contact with the platten. Directly adjacent to the platten were two heated, rubber covered, nip rolls which were moving in counter-rotation at a linear speed of 30 cm/minute and which were gapped so as to lightly compress the laminate of non-woven/plate as it was introduced into the nip roll gap. After a few seconds of warm-up time on the platten, the laminate was gently pushed into the nip roll gap.

After the laminate body eliminated from the heated nip, the CEREX™ non-woven web was gently lifted from the heated surface of the relief-forming layer with steady tension. It was noted that the uncured areas of the relief-forming layer of the printing plate had been removed via absorption of the thermoplastic uncured portions of the relief-forming layer into the non-woven web.

A half-tone image of the crown at 52.4 lines/cm was evident in the cured relief-forming layer of the plate. Two additional trips of the cured product through the heated nip of the laminator with fresh CEREX™ non-woven web sections were required to complete the removal of the unexposed areas of the plate. In a similar manner, the other photographic negative color seperations (black, cyan, yellow) of the crown slide were processed into flexographic printing plates for use in color printing.

Printing was accomplished utilizing a 5 station Webtron™ Model 525 flexographic printing press and water based flexographic printing inks (Louis Werneke Co.) with a tag and label printing base being utilized.

Printing was done under standard conditions utilized in traditional flexographic printing practice. An excellent rendition of the crown picture was reproduced in this way.

### (Evaluation of Flexographic Printing Plate)

The performance of a flexographic printing plate was evaluated with respect to the items below. The results are shown in Table 1.

### (1) Developability

Removal of unexposed and uncured region of a relief-forming layer (development, carried out in order to complete production of a flexographic printing plate) was carried out as follows. A nonwoven spun-bonded nylon porous web having a basis weight of 66 g/m² (Cerex™ spun-bonded nylon, James River) was cut into dimensions that conformed to a region of the printing plate to be treated. The nonwoven web layer was contacted with the relief-forming layer of the exposed printing plate precursor. This laminate was placed on a platen that was heated so that the surface of the polyester film of the printing plate in contact with the platen became 135° C. Two heated rubber-covered nip rolls were provided directly adjacent to the platen. These nip rolls were counter-rotated at a line speed of 30 cm/min, and a gap was provided so that the nonwoven web/printing plate laminate was appropriately pressed when it was introduced into the nip roll gap. After being heated for a few seconds on the platen, this laminate was gradually introduced into the nip roll gap.

After development, recessed parts of the relief of the entire printing plate were visually examined, and evaluation was carried out according to the degree of residual unexposed portion due to poor development. The less residue there was, the better the developability.

A: hardly any residue was observed
B: there was slight residue but at a level without any practical problems
C: residue was found in all locations

### (2) Printing Durability

A flexographic printing plate that had been obtained was set in a printer (Model ITM-4, IYO KIKAI SEISAKUSHO Co., Ltd.). As the ink, Aqua SPZ16 Red aqueous ink (Toyo Ink Manufacturing Co., Ltd.) was used without dilution, or a solvent ink was used. Printing was carried out continuously using Full Color Foam M 70 (Nippon Paper Industries Co., Ltd., thickness 100 μm) as the printing paper, and a highlight of 1% to 10% was confirmed for a printed material. The end of printing was defined when there was a halftone dot that was not printed, and the length (meters) of paper that was printed up to the end of printing was used as an index. The larger the value, the better the printing durability.

### (3) Aqueous Ink Laydown and Solvent Ink Laydown

The degrees of ink attachment in solid printed areas on printed materials at 1,000 m after starting printing in the evaluation of printing durability were visually compared.

The evaluation criteria were as follows.

A: uniform without density unevenness
B: there was partial density unevenness but at a level without any practical problems
C: there was unevenness

### (4) Relief Shape

The dot shape (3 point size, relief depth of 30 μm) on the printing plate (5 cm×5 cm) after development was examined by an optical microscope; one with a clear cone or pyramid shape was evaluated as A, when there were 10 or more dots with distorted dot lower parts or missing dot upper parts the evaluation was C (one evaluated as A having less than 3), and when there were 3 to 9 dots with distorted dot lower parts or missing dot upper parts the evaluation was B.

### Examples 2 to 18 and Comparative Examples 1 to 3

Flexographic printing plate precursors were prepared and plates were made in the same manner as in Example 1 except that Component A, Component C and Component D were changed as described in Table 1 and Table 2, and evaluation was carried out in the same manner.

The results are shown in Table 1 and Table 2.

TABLE 1

| | | | | | (C) Ethylenically | (D) Plasticizer | | Printing | | | |
|---|---|---|---|---|---|---|---|---|---|---|---|
| | | | | | unsaturated compound | (20 parts by | | durability (m) | | | |
| | (A) Polymer (50 parts by weight) | | | | (30 parts by weight) | weight) | | *Solvent ink | Aqueous ink | Solvent ink | |
| | Product name | | Tg (° C.) | Polar group | Product name | Product name | Developability | used for ink | laydown | laydown | Relief shape |
| Example 1 | S-LEC BL-1H | Polyvinyl butyral | 63 | OH group | Blemmer PDE-100 | ADK Cizer | A | 82,000 | A | A | A |
| | (Sekisui | | | Ether group | (NOF Corporation) | RS-540 | | | | | |
| | Chemical Co., | | | | | (ADEKA) | | | | | |
| | Ltd.) | | | | | | | | | | |
| Example 2 | S-LEC BM-2 | Polyvinyl butyral | 67 | OH group | Blemmer PDE-100 | ADK Cizer | A | 83,000 | A | A | A |
| | (Sekisui | | | Ether group | (NOF Corporation) | RS-540 | | | | | |
| | Chemical Co., | | | | | (ADEKA) | | | | | |
| | Ltd.) | | | | | | | | | | |
| Example 3 | S-LEC BM-S | Polyvinyl butyral | 60 | OH group | Blemmer PDE-100 | ADK Cizer | A | 83,000 | A | A | A |
| | (Sekisui | | | Ether group | (NOF Corporation) | RS-540 | | | | | |
| | Chemical Co., | | | | | (ADEKA) | | | | | |
| | Ltd.) | | | | | | | | | | |
| Example 4 | S-LEC BL-S | Polyvinyl butyral | 61 | OH group | Blemmer PDE-400 | ADK Cizer | A | 81,000 | A | A | A |
| | (Sekisui Chemical Co., | | | Ether group | (NOF Corporation) | RS-540 | | | | | |
| | Ltd.) | | | | | (ADEKA) | | | | | |
| Example 5 | S-LEC BM-S | Polyvinyl butyral | 60 | OH group | Blemmer PDE-400 | ADK Cizer | A | 82,000 | A | A | A |
| | (Sekisui | | | Ether group | (NOF Corporation) | RS-540 | | | | | |
| | Chemical Co., | | | | | (ADEKA) | | | | | |
| | Ltd.) | | | | | | | | | | |
| Example 6 | Mowital B60H | Polyvinyl butyral | 68 | OH group | Blemmer PDE-400 | ADK Cizer | A | 84,000 | A | A | A |
| | (Kuraray Co., Ltd.) | | | Ether group | (NOF Corporation) | RS-540 | | | | | |
| | | | | | | (ADEKA) | | | | | |
| Example 7 | Mowital B30HH | Polyvinyl butyral | 60 | OH group | Blemmer PDBE-400 | ADK Cizer | A | 82,000 | A | A | A |
| | (Kuraray Co., Ltd.) | | | Ether group | (NOF Corporation) | RS-540 | | | | | |
| | | | | | | (ADEKA) | | | | | |
| Example 8 | PVA205 (The Nippon | Polyvinyl alcohol | 85 | OH group | Blemmer PDE-100 | None | B | 80,000 | A | B | A |
| | Synthetic Chemical | | | | (NOF Corporation) | | | | | | |
| | Industry Co., Ltd.) | | | | | | | | | | |
| Example 9 | Gohsenal T330H (The | Polyvinyl alcohol | 80 | OH group | Blemmer PDE-100 | Diethylene | A | 80,000 | A | B | A |
| | Nippon Synthetic | | | | (NOF Corporation) | glycol | | | | | |
| | Chemical Industry Co., | | | | | | | | | | |
| | Ltd.) | | | | | | | | | | |
| Example | Vylon UR-1350 | Polyester | 46 | Ester group | Blemmer PDBE-450 | Tributyl citrate | A | 80,000 | A | A | A |
| 10 | (Toyobo Co., Ltd.) | polyurethane resin | | | (NOF Corporation) | (Wako Pure | | | | | |
| | | | | | | Chemical) | | | | | |

TABLE 2

| | | | | | (C) Ethylenically | | | Printing | | | |
|---|---|---|---|---|---|---|---|---|---|---|---|
| | | | | | unsaturated compound | (D) Plasticizer (20 | | durability (m) | Aqueous | Solvent | |
| | (A) Polymer (50 parts by weight) | | | | (30 parts by weight) | parts by weight) | | *Solvent ink | ink | ink | Relief |
| | Product name | | Tg (° C.) | Polar group | Product name | Product name | Developability | used for ink | laydown | laydown | shape |
| Example 11 | Vylon 220 | Amorphous polyester | 53 | Ester group | Blemmer PDBE-450 | Tributyl citrate | A | 78,000 | A | A | A |
| | (Toyobo Co., Ltd.) | resin | | | (NOF Corporation) | (Wako Pure | | | | | |
| | | | | | | Chemical) | | | | | |
| Example 12 | Vylon 226 | Amorphous polyester | 65 | Ester group | Blemmer PDBE-450 | Tributyl citrate | A | 77,000 | A | A | A |
| | (Toyobo Co., Ltd.) | resin | | | (NOF Corporation) | (Wako Pure | | | | | |
| | | | | | | Chemical) | | | | | |
| Example 13 | Vyloecol BE-400 | Amorphous polylactic | 50 | Ester group | Blemmer PDBE-450 | Tributyl citrate | A | 77,000 | A | A | A |
| | (Toyobo Co., Ltd.) | acid resin | | | (NOF Corporation) | (Wako Pure | | | | | |
| | | | | | | Chemical) | | | | | |
| Example 14 | Poly(methyl | (Meth)acrylic resin | 110 | Ester group | Blemmer PDBE-450 | Tributyl citrate | A | 75,000 | B | A | A |
| | methacrylate) (Aldrich) | | | | (NOF Corporation) | (Wako Pure | | | | | |
| | | | | | | Chemical) | | | | | |
| Example 15 | Marproof G-0150M | (Meth)acrylic resin | 71 | Ester group | Blemmer PDBE-450 | Tributyl citrate | A | 74,000 | B | A | A |
| | (NOF Corporation) | | | | (NOF Corporation) | (Wako Pure | | | | | |
| | | | | | | Chemical) | | | | | |
| Example 16 | Polycarbonate (Aldrich) | Polycarbonate resin | 147 | Other | Blemmer PDBE-450 | Tributyl citrate | A | 72,000 | B | A | A |
| | | | | | (NOF Corporation) | (Wako Pure | | | | | |
| | | | | | | Chemical) | | | | | |
| Example 17 | Metolose SM (Shin-Etsu | Methylcellulose | 100 | Other | Blemmer PDBE-450 | Tributyl citrate | A | 72,000 | A | B | A |
| | Chemical Co., Ltd.) | | | | (NOF Corporation) | (Wako Pure | | | | | |
| | | | | | | Chemical) | | | | | |
| Example 18 | Metolose GOSH (Shin- | Methylcellulose | 100 | Other | Blemmer PDBE-450 | Tributyl citrate | A | 72,000 | A | B | A |
| | Etsu Chemical Co., | | | | (NOF Corporation) | (Wako Pure | | | | | |
| | Ltd.) | | | | | Chemical) | | | | | |
| Comp. Ex. 1 | TR-2000 (JSR) | Synthetic rubber | 1st. −78 | — | Blemmer PDBE-450 | Tributyl citrate | C | 70,000 | C | B | C |
| | | (SBR) | 2nd. 100 | | (NOF Corporation) | (Wako Pure | | | | | |
| | | | | | | Chemical) | | | | | |
| Comp. Ex. 2 | S-LEC BL-1H (Sekisui | Polyvinyl butyral | 63 | OH group | EBECRYL 230 | Tributyl citrate | C | 50,000 | C | B | C |
| | Chemical Co., Ltd.) | | | Ether group | (Daicel-Cytec Company | (Wako Pure | | | | | |
| | | | | | Ltd.) | Chemical) | | | | | |
| Comp. Ex. 3 | Polyurethane elastomer A | Polyurethane resin | <25 | — | Blemmer PDBE-450 | Tributyl citrate | C | 60,000 | B | C | B |
| | | | | | (NOF Corporation) | (Wako Pure | | | | | |
| | | | | | | Chemical) | | | | | |

What is claimed is:

1. A flexographic printing plate precursor for thermal development, comprising:
a relief-forming layer on/above a support; the relief-forming layer comprising
(Component A) a polymer having a glass transition temperature (Tg) of at least 25° C.,
(Component B) a photopolymerization initiator, and
(Component C) an ethylenically unsaturated compound having a molecular weight of no greater than 3,000.

2. The flexographic printing plate precursor for thermal development according to claim 1, wherein the relief-forming layer further comprises (Component D) a plasticizer.

3. The flexographic printing plate precursor for thermal development according to claim 1, wherein Component A has a polar group.

4. The flexographic printing plate precursor for thermal development according to claim 2, wherein Component A has a polar group.

5. The flexographic printing plate precursor for thermal development according to claim 3, wherein the polar group of Component A is selected from the group consisting of an ester bond, an ether bond, and a hydroxy group.

6. The flexographic printing plate precursor for thermal development according to claim 4, wherein the polar group of Component A is selected from the group consisting of an ester bond, an ether bond, and a hydroxy group.

7. The flexographic printing plate precursor for thermal development according to claim 1, wherein Component A is selected from the group consisting of polyvinyl alcohol and a derivative thereof, polyvinyl acetal and a derivative thereof, polyester, polyester polyurethane, polylactic acid, a (meth)acrylic resin, a polycarbonate resin, and a polysaccharide.

8. The flexographic printing plate precursor for thermal development according to claim 5, wherein Component A is selected from the group consisting of polyvinyl alcohol and a derivative thereof, polyvinyl acetal and a derivative thereof, polyester, polyester polyurethane, polylactic acid, a (meth)acrylic resin, a polycarbonate resin, and a polysaccharide.

9. The flexographic printing plate precursor for thermal development according to claim 1, wherein Component A is polyvinyl acetal and/or a derivative thereof.

10. The flexographic printing plate precursor for thermal development according to claim 8, wherein Component A is polyvinyl acetal and/or a derivative thereof.

11. The flexographic printing plate precursor for thermal development according to claim 1, wherein the relief-forming layer comprises Component A at 30 to 90 wt %.

12. The flexographic printing plate precursor for thermal development according to claim 2, wherein the relief-forming layer comprises Component D at 1 to 30 wt %.

13. The flexographic printing plate precursor for thermal development according to claim 2, wherein Component D is selected from the group consisting of a citric acid derivative, a polyethylene glycol, and a polypropylene glycol.

14. The flexographic printing plate precursor according to claim 1, wherein Component C is a 2- to 6-functional (meth)acrylate.

15. The flexographic printing plate precursor according to claim 1, wherein the flexographic printing plate precursor further comprises an adhesive layer between the relief-forming layer and the support.

16. A process for making a flexographic printing plate, comprising
(Step a) an exposure step of imagewise exposing a relief-forming layer of a flexographic printing plate precursor;
(Step b) a heating step of heating the exposed flexographic printing plate precursor at a temperature of 40° C. to 270° C.; and
(Step c) a development step of removing an unexposed portion that has become softened by heating,
the flexographic printing plate precursor comprising the flexographic printing plate precursor for thermal development according to claim 1.

17. The process for making a flexographic printing plate according to claim 16, wherein the exposure step is a step of imagewise irradiating the relief-forming layer with UV.

18. The process for making a flexographic printing plate according to claim 16, wherein the exposure step is a step of curing an exposed portion by crosslinking and/or polymerization.

19. The process for making a flexographic printing plate according to claim 16, wherein the development step comprises a step of removing the unexposed portion of the relief-forming layer that has become softened by heating by contacting with an absorbent member.

20. The process for making a flexographic printing plate according to claim 16, wherein it further comprises a backside irradiation step of irradiating the relief-forming layer by applying actinic radiation toward the support and making it pass through the support.
